(19) United States
(12) Patent Application Publication
(10) Pub. No.: US 2017/0363667 A1
(43) Pub. Date: Dec. 21, 2017

(54) DIGITAL PHASE METER AND PHASE DETECTION METHOD

(71) Applicant: LEONARDO MW LTD, Essex (GB)

(72) Inventor: Christopher Edward GREGORY, Essex (GB)

(73) Assignee: LEONARDO MW LTD, Essex (GB)

(21) Appl. No.: 15/533,317

(22) PCT Filed: Dec. 21, 2015
(86) PCT No.: PCT/EP2015/080823

§ 371 Date: Jun. 5, 2017

(30) Foreign Application Priority Data
Dec. 19, 2014 (GB) 1422851.4

(51) Int. Cl. G01R 25/00

(52) U.S. Cl. CPC G01R 25/005

(57) ABSTRACT

A wideband digital phase meter and phase detection method are disclosed. The device measures a phase difference between 2 signals and is suitable for integration into a single MMIC. The input signals are compared digitally by using two EXOR gates and integrated over a phase comparison period. The resultant analogue signals are digitised using an Analogue to Digital convertor. Additionally, 2×D-Type registers are used to resolve the (0° to 180°) or (180° to 360°) ambiguity of the EXOR phase detector.

The invention relates to a digital phase meter. More specifically but not exclusively it relates to digital phase meters for use in Electronic Warfare Receivers and or Digital Microwave Monolithic Microwave Integrated Circuits (MMICs).

A phase detector or phase comparator is a frequency mixer, analogue multiplier or logic circuit that generates a voltage signal which represents the difference in phase between two signal inputs. It is commonly used in phase-locked loop (PLL) circuits.

Detecting phase difference is also very important in many applications, such as motor control, radar, electronic warfare and telecommunication systems, servo mechanisms, and demodulators.

There are two main types of phase detectors, analogue and digital.

Digital phase detectors are primarily designed for PLLs (Phase Locked Loops). They are commonly made from EXOR (Exclusive OR) gates and flip-flops. Periodic pulses are generated, the widths of which are proportional to phase difference between 2 input signals.

The second type of phase detector is an analogue phase detector, for example as described in Microwave Passive Direction Finding” by Stephen E Lipsky, 2003, ISBN: 1891121235. (See “Wideband class III phase correlator”)

Such analogue phase detectors, as described therein, are commonly used in Frequency Measurement and Angle of Arrival (AoA) determination by phase interferometry. An analogue phase detector of this type is, for example, constructed using a 180° hybrid, 3×90° hybrids, power combiners and 4× detectors.

Such phase detectors generate sinφ, −sinφ, cosφ and −cosφ outputs. These outputs are then converted to sin and cos in digital format. The phase difference between the two input signals is then determined by the arc tan of the sin/cos signals.

There are problems associated with these types of phase detectors for EW applications.

Digital phase detectors are not generally used in EW applications such as EW phase interferometry as the accuracy required for such applications cannot be achieved.

With regard to analogue phase detectors, whilst such detectors are currently used in EW phase interferometry, there are problems associated with the devices and the method used.

The most compact form of wideband “90° hybrid” phase detector in use in EW applications is a “Lange coupler”. These, for low frequencies, are physically large and cumbersome. Additionally, it is difficult to achieve accurate analogue designs with much more than 3:1 bandwidth (e.g. 2 GHz to 6 GHz or 6 GHz to 18 GHz). Therefore, for EW applications where a full RADAR bandwidth is required, 2 devices must be used.

Moreover, it is not possible to construct a complete monolithic circuit using this analogue method. Therefore, due to lack of high integration, cost, power consumption and size of complete circuits can be high.

The invention aims to overcome these and other problems with existing systems.

The invention provides a wide bandwidth Digital Phase Meter, using a technique of cross-coupled EXOR gates and D-Flip-flops to reduce phase measurement error.

According to the invention there is provided a wideband phase meter comprising a first IP buffer Y, a first phase detector B and a first ambiguity resolver Y arranged in a mirror image in a horizontal plane with a second IP buffer X, a second phase detector A and a second ambiguity resolver X such that combination of the A and B channels by suitable combining means results in an output signal substantially free from distortion.

According to the invention there is further provided a method of reducing phase measurement error in a wideband phase meter comprising the steps of: cross-coupling EXOR gates and D-Flip-flops to reduce phase measurement error.

The device measures the phase difference between 2 signals and is suitable for integration into a single MMIC. This has been demonstrated using a Silicon Germanium high transition frequency (Ft) high maximum oscillation frequency (Fmax) process.

The device and method in accordance with the invention is applicable for use with signals from a 20:1 frequency range in the RADAR band with high accuracy. The input signals are compared digitally by using two EXOR gates and integrated over the phase comparison period. The resultant analogue signals are digitised using an Analogue to Digital convertor. Additionally, 2×D-Type registers are used to resolve the (0° to 180°) or (180° to 360°) ambiguity of the EXOR phase detector. The duplication, and mirroring, of the EXOR and D-Types, their cross-coupling of their inputs and subsequent processing of their outputs is the subject of this invention.

The phase detector in accordance with the invention is most similar to conventional Digital Phase Detectors, but utilises 2 differential EXOR cross-coupled gates, with their outputs combined in order to reduce the error in the phase detector.

Additionally, there are two D-Type registers, used to resolved the Phase Detector ambiguity, so that if they are both at the same state, then the resulting Phase Angle given is forced to either 0° or 180° depending upon the value given by the phase detector.

In this way, the accuracy of the digital phase meter is improved over conventional types.

It should be noted that the invention is not for use in a PLL system, but for EW

Phase measurement in the RADAR band.

Furthermore, the device and method in accordance with the invention differs from the Analogue Phase Detector in a number of ways. For example, the function can now be implemented in a single MMIC with a frequency range so that it can be used over a 20:1 frequency range in the RADAR band; no down-conversion or use of mixers is required for a 20:1 frequency range; and it does make use of 90° nor 180° hybrids, and therefore more suitable for MMIC integration. It will be appreciated that A 90° hybrid has 2 outputs. One +45° phase shifted relative to the input, the other −45° phase shifted. Similarly for 180° hybrid—his has ±90° outputs. In order to make these devices, signals are delayed using long track lengths, these have to be a certain fraction of the signal wavelength, and for low frequencies these are long.

The present invention is suitable for use with pulsed or CW signals.

The invention will now be described with reference to the accompanying diagrammatic drawings in which:

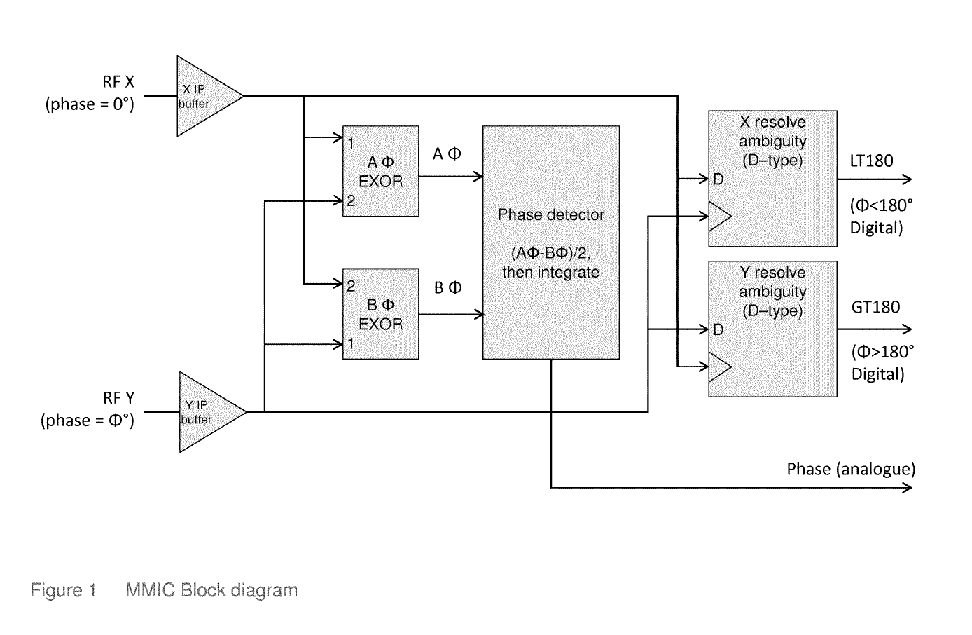

FIG. 1 is a schematic block diagram of a wideband phase meter in accordance with one form of the invention;

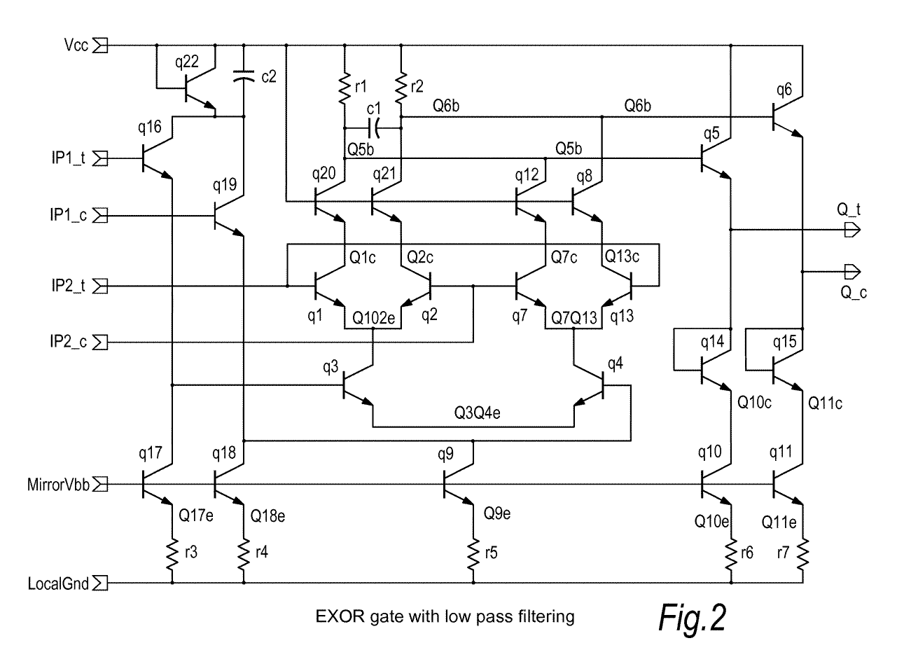

FIG. 2 is a schematic circuit diagram for the EXOR gate with low pass filtering for the phase detector shown in FIG. 1;

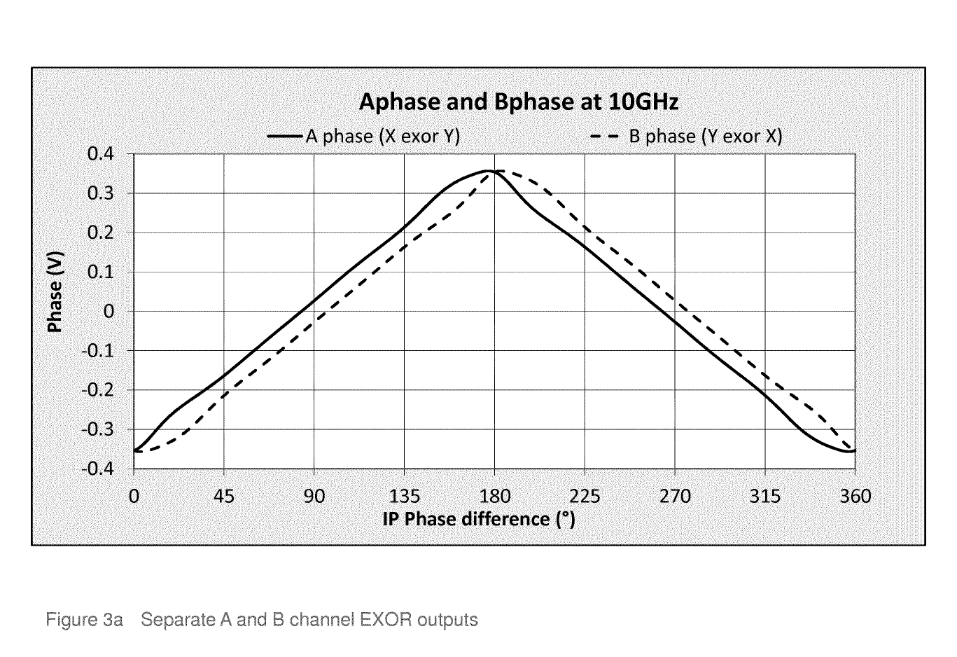

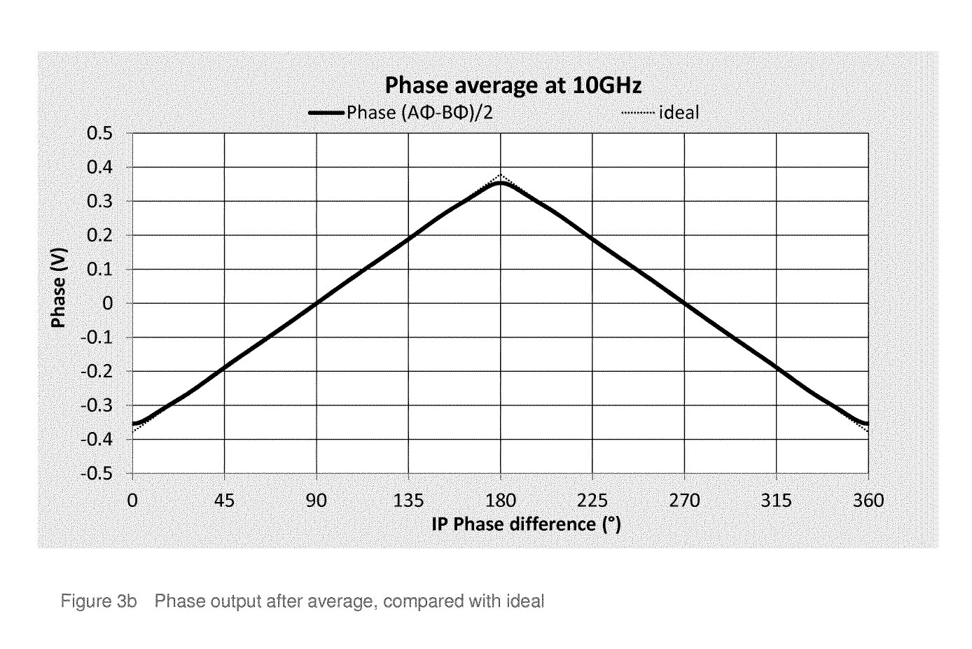

FIGS. 3a is a graph showing the A and B channel EXOR outputs for the circuits of FIGS. 1 and 2. Note that each independent EXOR output has distortion, arising to phase detector errors. FIG. 3b shows the result of taking the average of the two outputs and compares this with the ideal output. The ‘Phase’ OP at 10 GHz of the average of channels A and B shows little distortion of the output signal;

Note that FIG. 3b illustrates that the ‘Phase’ output alone is insufficient for a phase detector as it is ambiguous of what phase angle region (0° to 180° or 180° to 360°) the answer lies. For example an output voltage of 0.1V could indicate the phase angle is 114° or 246°.

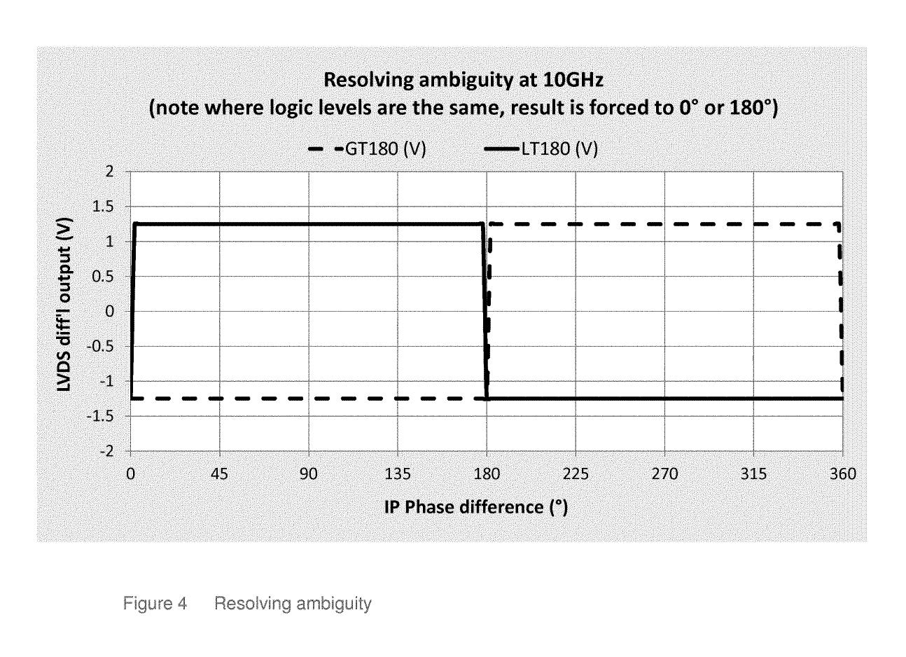

FIG. 4 shows the output from the two D-Types that are used for resolving this ambiguity. One has the output ‘LT180’ (i.e. the signal lies is Less Than 180°) the other has the output ‘GT180’ (i.e. Greater Than 180°). Confusingly, in the phase angle regions around 0° and 180°, it is possible that both outputs can be logic TRUE. This would indicate that the signal is both greater and less than 180°. Ideally this should not happen, but due to the imperfections in the design due to transistor bandwidths and path delay matching is does occur for a small range of angles. If it does occur, then the phase angle is forced to give a value of exactly 0° or 180° dependent upon whether the ‘Phase’ output is greater or less than 0 volts.

This is part of the invention.

For clarity, in the present description, the whole MMIC is named a “Digital Phase Meter”, as it measures phase difference, between the X and Y RF input ports mainly using digital circuits.

FIG. 1 shows the block diagram of the complete DPM MMIC. The IP buffer Y, phase detector B and ambiguity resolver Y have their physical layouts in the circuits as reflections (in the horizontal axis) of the IP buffer X, phase detector A and ambiguity resolver X, respectively. The phase detectors are formed from EXOR gates and a Heterojunction Bipolar Transistor (HBT) implementation of such EXOR gates is shown in FIG. 2.

The first stage is converting the RF inputs into differential digital signals, at the appropriate level for SiGe.

There are also additional buffers to split the digitised RF signal 4 ways to the various processing blocks.

An EXOR gate has a logic 1 output when the inputs are different and logic 0 when the same. The DPM uses this to compare how in-phase the 2 signals are. Note that when the signals are only 1° apart, the resulting logic 1 pulse is only 0.14 ps (50 ps/360) long. This underlines why the need the 200 GHz Ft/Fmax speed of the SG25H1 process.

In the present invention, C1 is added as the integrator capacitor. This capacitor turns the differential digital output Q into an analogue signal in proportion to the MARK/SPACE ratio of IN. EXOR IP2 a number of RF cycles.

The outputs from the EXOR gates have to be integrated. This turns the high frequency mark/space ratio digital signal into an analogue voltage which is proportional to phase (in the 0° to 180° region).

This also acts as a low pass filter, improving signal to noise ratio.

Unfortunately this EXOR integrator is ambiguous. Using the integrator alone it is not possible to distinguish whether signals have phase difference in the 0° to 180° region or the 180° to 360° region.

It can be seen in FIG. 1 that there are 2 sets of circuits and it is a symmetrical design.

The EXOR gate has 2 levels of logic. The top half behaves slightly differently from the bottom half. See FIG. 2 and the circuits associated with IP1 and IP2. This asymmetry causes the non-triangular shape of FIG. 3a, where the A channel (X EXOR Y) and B channel (Y EXOR X) outputs are shown.

This technique in accordance with one aspect of the invention has a remarkable effect. When the A and B channels are averaged together, virtually all the distortion vanishes. The result (after further output buffering) is the graph of FIG. 3b.

Consider the case where X and Y inputs are phase aligned. This should give Q at a 3.0 minimum, since an EXOR gate has logic output of 1 if the inputs are different, and 0 when they are the same.

This type of EXOR requires the upper differential pairs (q1/q2 and q7/q13) to be switched after the lower pair (q3/q4) has switched for no phase error.

It is possible to partially correct this required additional delay by adding an extra transistor delay in the IP2 path. The rest of the delay, at room temperature and at design centre, can be reduced by careful design of differential track path delay. However, with temperature and process variations, this may not be ideal.

The effect of adding this extra path delay on the outputs of the phase detectors A, B is shown in FIG. 4. The peak of the phase detector A and the trough of the phase detector B should occur at 180° for 0° error.

Additional delay for the phase detector A (green trace in diagram/dotted line) skews the peak to the right with increasing delay, whereas it skews to the left for the phase detector B (red trace/dashed line).

By making the subtraction A-B, it forces symmetry about the 180°, and this reduces the phase measurement error.

However, if there is a skew error in the phase detectors A B, then a small plateau will occur at 0° and 180°. This is not possible to remove with this technique.

The Phase Detector (A-B) output is converted to digital using an ADC either on or off the MMIC.

A similar technique is also used with the circuits that resolve the ‘Phase Ambiguity’, whether the signal is in the (0° to 180°) or (180° to 360°) portion of the detector output. Such a phase ambiguity is resolved using a D-Type latch.

The ambiguity resolver X gives a Logic 1 output if the phase difference between X and Y is 0° to 180°, otherwise logic 0. The D input of the ambiguity resolver X comes from the X input, and the clock signal comes from the Y input.

Conversely the ambiguity resolver Y gives a Logic 1 output if the phase difference between X and Y is 180° to 360°, otherwise logic 0. The D input of the ambiguity resolver Y comes from the Y input, and the clock signal comes from the X input.

Ideally the X and Y ambiguity detectors should always give the opposite state. Again, because of imperfections in cancelling out the logic delays, they can both give the same output.

The regions where this can occur is around 0° and 180°, but the phase detectors can easily distinguish whether the fault is occurring at 0° or 180°. So, in the event of these outputs being at the same state, the final reported phase angle is forced to exactly 0° or 180°, as appropriate.

A more detailed example of resolving the ambiguity now follows.

A D-type latch is clocked by the X RF input, with the data input being the Y channel RF. This then gives the ability to see whether X leads or lags Y RF. This is shown in the ‘phase is <180° ’ block in FIG. 1. Again a symmetrical design is used. 1° error is caused by a 140 fs timing error at 20 GHz. With a monolithic circuit, both halves of the design will be extremely well matched. SiGe has excellent tracking accuracy between transistors and resistors in close proximity. So, by having 2 D-Types latches (one with the X channel on the clock, the other with the Y channel) any tracking, transistor delay variation is cancelled out.

Each D-Type has an averaging circuit following, to reduce noise effects. These two averaging circuits have analogue outputs and are combined with a 2 bit Analogue to Digital Converter (ADC). The two bits are labelled GT180 and LT180.

This ADC has built-in hysteresis to avoid oscillation when the phase difference is 3.0 around 0° or 180°. In those regions GT180 =LT180. The region is narrow (<5°), but this is used to force the detected phase either to 0° (if ‘Phase’ <0V) or 180° (if ‘Phase >0V). This helps to reduce the error caused by the plateau of the Phase triangular waveform that occurs around 0° and 180°.

This technique reduces by half what the error would be with a single D-Type.

Conventional digital phase detectors, used commonly in Pas, only have a single EXOR and D-Type registers (for resolving ambiguity).

The duplication, and mirroring, of the EXOR and D-Types, the cross-coupling of their inputs and subsequent processing of their outputs is the subject of this invention.

1. A wideband phase meter comprising:
a B channel having a first IP buffer Y, a first phase detector B, and a first ambiguity resolver Y arranged in a mirror image in a horizontal plane with an A channel having a second IP buffer X, a second phase detector A and a second ambiguity resolver X; and
combining means for combination of the A and B channels to provide an output signal substantially free from distortion.

2. A wideband phase meter according to claim 1, in which the first and second phase detectors comprise:
two differential EXOR cross-coupled gates, outputs of the EXOR gates being combined in order to reduce error in phase detection.

3. A wideband phase meter according to claim 1, comprising:
two D-Type registers, said registers having ambiguity resolution means for acting to resolve any phase detector ambiguity in the output signal of the phase meter, and being configured such that when both registers are in a same state, then a resulting phase angle output is forced.

4. A method of reducing phase measurement error in a wideband phase meter, the method comprising:
cross-coupling EXOR gates and D-Flip-flops of the wideband phase meter to reduce phase measurement error.

5. A wideband phase meter according to claim 2, comprising:
two D-Type registers, said registers having ambiguity resolution means for acting to resolve any phase detector ambiguity in the output signal of the phase meter, and being configured such that when both registers are in a same state, then a resulting phase angle output is forced.

6. The method of claim 4, wherein the wideband phase meter includes:
a B channel having a first IP buffer Y, a first phase detector B, and a first ambiguity resolver Y arranged in a mirror image in a horizontal plane with an A channel having a second IP buffer X, a second phase detector A and a second ambiguity resolver X; and
combining means for combination of the A and B channels to provide an output signal substantially free from distortion.
